(19) United States
(12) Patent Application Publication
(10) Pub. No.: US 2024/0290818 A1
(43) Pub. Date: Aug. 29, 2024

(54) DISPLAY DEVICE

(71) Applicant: LG DISPLAY CO., LTD., Seoul (KR)

(72) Inventors: Gwangmin YEO, Goyang-si (KR); WonJun CHOI, Paju-si (KR); SeongHwan JU, Paju-si (KR); Sangmin PARK, Gimpo-si (KR)

(73) Assignee: LG DISPLAY CO., LTD., Seoul (KR)

(21) Appl. No.: 18/583,169

(22) Filed: Feb. 21, 2024

(30) Foreign Application Priority Data
Feb. 28, 2023 (KR) 10-2023-0027187

(51) Int. Cl. H01L 27/15; H01L 33/60

(52) U.S. Cl. CPC H01L 27/156; H01L 33/60

(57) ABSTRACT

A display device includes a substrate including an active area in which the plurality of sub pixels is disposed and a non-active area which encloses the active area; a plurality of pad electrodes disposed on the substrate in the non-active area to transmit a signal to the plurality of sub pixels and each including a first conductive layer, a second conductive layer on the first conductive layer, and a third conductive layer on the second conductive layer; a first passivation layer extending from the active area to cover an end of the first conductive layer; and a second passivation layer extending from the active area to cover an end of the second conductive layer.

### CROSS-REFERENCE TO RELATED APPLICATION

This application claims the priority of Korean Patent Application No. 10-2023-0027187 filed on Feb. 28, 2023, which is hereby incorporated by reference in its entirety.

### BACKGROUND

### Field of the Disclosure

The present disclosure relates to a display device, and more particularly, to a display device using a light emitting diode (LED).

### Description of the Background

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance may be displayed.

### SUMMARY

Accordingly, the present disclosure is to provide a display device which can minimize a defect due to erosion of a side surface of a pad electrode caused during the processing process.

In addition, the present disclosure is to provide a display device which can minimize heat generated in a pad electrode.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device including a substrate including a display area including a plurality of sub pixels is disposed and a non-active area adjacent to the active area; a plurality of pad electrodes disposed on the substrate in the non-active area to transmit a signal to the plurality of sub pixels and each including a first conductive layer, a second conductive layer disposed on the first conductive layer, and a third conductive layer disposed on the second conductive layer; a first passivation layer extending from the active area and disposed on a portion of the first conductive layer; and a second passivation layer extending from the active area and covering an end of the second conductive layer.

In another aspect of the present disclosure, a display device including a substrate defined by a display area including a plurality of sub pixels and a non-active area adjacent to the active area; a pad electrode comprising first, second and third conductive layers and disposed in the non-active area to transmit a signal to the plurality of sub pixels and; and a first passivation layer extending from the active area, disposed on the first conductive layer and having at least one contact hole, wherein the first conductive layer and the second conductive layer are in contact through the at least one contact hole.

According to various aspects of the present disclosure, a defect of the pad electrode generated during the processing process may be minimized.

According to various aspects of the present disclosure, the heat generated in the pad electrode may be minimized to improve the reliability of the display device.

It is to be understood that both the foregoing general description and the following detailed description are exemplary and explanatory and are intended to provide further explanation of the disclosure as claimed.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary aspect of the present disclosure;

FIG. 2A is a partial cross-sectional view of a display device according to an exemplary aspect of the present disclosure;

FIG. 2B is a perspective view of a tiling display device according to an exemplary aspect of the present disclosure;

FIG. 3A is a plan view of a display panel before grinding a display device according to an exemplary aspect of the present disclosure;

FIG. 3B is a plan view of a display panel after grinding a display device according to an exemplary aspect of the present disclosure;

FIG. 3C is an enlarged plan view of area B of FIG. 3B;

FIGS. 4A and 4B are plan views illustrating a pixel area of a display device according to an exemplary aspect of the present disclosure;

FIG. 5 is a cross-sectional view of a pixel area of a display device according to an exemplary aspect of the present disclosure;

FIG. 6 is a cross-sectional view taken along A-A′ of FIG. 3B;

FIG. 7 is a cross-sectional view taken along C-C′ of FIG. 3B;

FIG. 8A is an enlarged plan view of one first pad electrode of a display device according to another exemplary aspect of the present disclosure; and

FIG. 8B is a cross-sectional view taken along D-D′ of FIG. 8A.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary aspects of the present disclosure are merely examples, and the present disclosure is not limited thereto Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including’, ‘having’, and ‘consist of’ used herein are generally intended to allow other components to be added unless the terms are used with the term ‘only’. Any references to singular may include plural unless expressly stated otherwise.

Components are interpreted to include an ordinary error range even if not expressly stated.

When the position relation between two parts is described using the terms such as ‘on’, ‘above’, ‘below’, ‘next’, and one or more parts may be positioned between the two parts unless the terms are used with the term ‘immediately’ or ‘directly’.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various aspects of the present disclosure may be partially or entirely adhered to or combined with each other and may be interlocked and operated in technically various ways, and the aspects may be carried out independently of or in association with each other.

Hereinafter, various aspects of the present disclosure will be described in detail with reference to accompanying drawings.

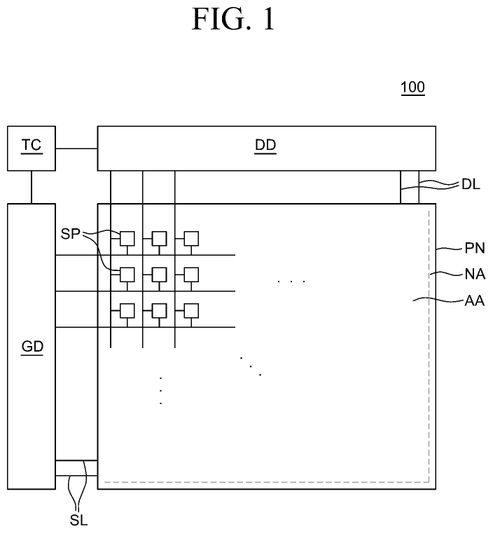

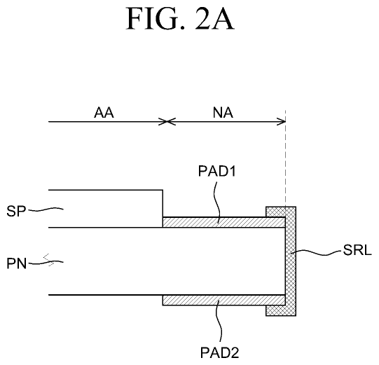

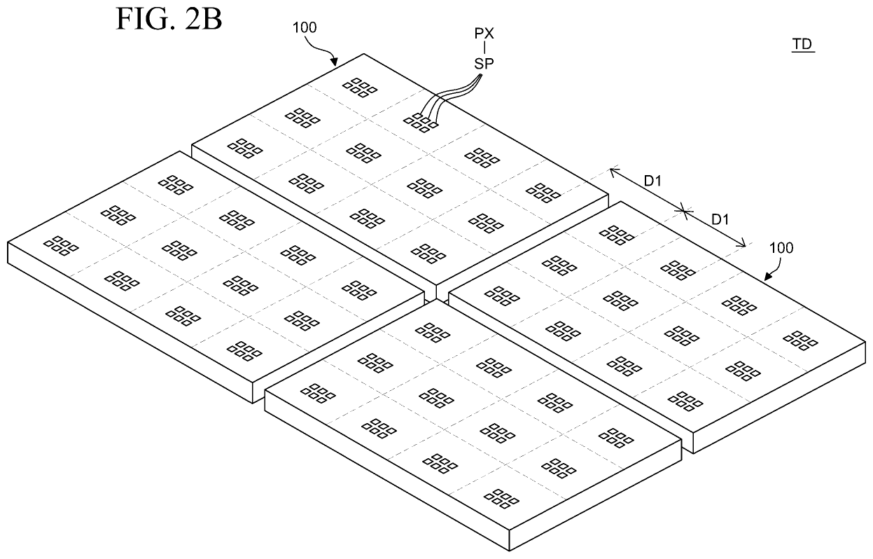

FIG. 1 is a schematic diagram of a display device according to an exemplary aspect of the present disclosure. FIG. 2A is a partial cross-sectional view of a display device according to an exemplary aspect of the present disclosure. FIG. 2B is a perspective view of a tiling display device according to an exemplary aspect of the present disclosure. In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL in accordance with a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other, and the plurality of sub pixels SP are connected to the scan lines SL and the data lines DL, respectively. In addition, each of the plurality of sub pixels SP may be connected to a high potential power line, a low potential power line, a reference line, and the like.

In the display panel PN, a display area AA and a non-display area NA enclosing the active area AA may be defined.

The active area AA is an area in which images are displayed in the display device 100. In the active area AA, a plurality of sub pixels SP which configure a plurality of pixels PX and a circuit for driving the plurality of sub pixels SP may be disposed. The plurality of sub pixels SP are a minimum unit which configures the active area AA and n sub pixels SP may form one pixel. In each of the plurality of sub pixels SP, a light emitting diode, a thin film transistor for driving the light emitting diode may be disposed. The plurality of light emitting diodes may be configured in different manners depending on the type of the display panel PN. For example, when the display panel PN is an inorganic light emitting display panel, the light emitting diode may be a light emitting diode (LED) or a micro light emitting diode (micro LED).

In the active area AA, a plurality of wiring lines which transmit various signals to the plurality of sub pixels SP is disposed. For example, the plurality of wiring lines may include a plurality of data lines DL which supply a data voltage to each of the plurality of sub pixels SP, a plurality of scan lines SL which supply a scan signal to each of the plurality of sub pixels SP, and the like. The plurality of scan lines SL extend in a direction in the active area AA to be connected to the plurality of sub pixels SP and the plurality of data lines DL extend in another direction different from the direction in the active area AA to be connected to the plurality of sub pixels SP. In addition, in the active area AA, a low potential power line, a high potential power line, and the like may be further disposed, but are not limited thereto.

The non-active area NA is an area where images are not displayed so that the non-active area NA may be configured as an area extending from the active area AA. In the non-active area NA, a link line which transmits a signal to the sub pixel SP of the active area AA, a pad electrode, a driving integrated circuit (IC), such as a gate driver IC and a data driver IC, or the like, may be disposed.

The non-active area NA may be located on a rear surface of the display panel PN, for example, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner For example, the data driver DD and the timing controller TC are formed in separate flexible film and printed circuit board. The data driver and the timing controller may be electrically connected to the display panel PN by bonding the flexible film and the printed circuit board to the pad electrode formed in the non-active area NA of the display panel PN.

If the gate driver GD is mounted in the GIP manner and the data driver DD and the timing controller TC transmit a signal to the display panel PN through a pad electrode of the non-active area NA, an area of the non-active area NA for disposing the gate driver GD and the pad electrode is necessary more than a predetermined level. Accordingly, a bezel may be increased.

In contrast, when the gate driver GD is mounted in the active area AA in the GIA manner and a side line which connects the signal line on the front surface of the display panel PN to the pad electrode on a rear surface of the display panel PN is formed to bond the flexible film and the printed circuit board onto a rear surface of the display panel PN, the non-active area NA may be minimized on the front surface of the display panel PN. For example, when the gate driver GD, the data driver DD, and the timing controller TC are connected to the display panel PN as described above, a zero bezel with substantially no bezel may be implemented.

For example, referring to FIGS. 2A and 2B, in the non-active area NA of the display panel PN, a plurality of pad electrodes PAD1 and PAD2 for transmitting various signals to the plurality of sub pixels SP are disposed. For example, in the non-active area NA on the front surface of the display panel PN, a plurality of first pad electrodes PAD1 which transmit a signal to the plurality of sub pixels SP are disposed. In the non-active area NA on the rear surface of the display panel PN, a plurality of second pad electrode PAD2 which are electrically connected to a driving component, such as a flexible film and the printed circuit board, are disposed. For example, on the front surface of the display panel PN on which images are displayed, only a pad area of the non-active area NA in which the first pad electrode PAD1 is disposed may be formed at minimum.

In this case, even though it is not illustrated in the drawing, various signal lines connected to the plurality of sub pixels SP, for example, a scan line SL or a data line DL extend from the active area AA to the non-active area NA to be electrically connected to the first pad electrode PAD1.

The side line SRL is disposed along a side surface of the display panel PN. The side line SRL may electrically connect a first pad electrode PAD1 on the front surface of the display panel PN and a second pad electrode PAD2 on the rear surface of the display panel PN. Therefore, a signal from a driving component on the rear surface of the display panel PN may be transmitted to the plurality of sub pixels SP through the second pad electrode PAD2, the side line SRL, and the first pad electrode PAD1. Accordingly, a signal transmitting path from the front surface of the display panel PN to the side surface and the rear surface is formed to minimize an area of the non-active area NA on the front surface of the display panel PN.

Referring to FIG. 2B, a tiling display device TD having a large screen size may be implemented by connecting a plurality of display devices 100. At this time, as illustrated in FIG. 2A, when the tiling display device TD is implemented using a display device 100 with a minimized bezel, a seam area in which an image between the display devices TD is not displayed is minimized so that a display quality may be improved.

For example, the plurality of sub pixels SP may form one pixel PX and a distance D1 between an outermost pixel PX of one display device 100 and an outermost pixel PX of another display device 100 adjacent to the one display device may be implemented to be equal to a distance D1 between pixels PX in the one display device 100. Accordingly, a distance D1 between pixels PX between the display devices 100 is constantly configured to minimize the seam area.

However, FIGS. 2A and 2B are illustrative so that the display device according to the exemplary aspect of the present disclosure may be a general display device with a bezel, but is not limited thereto.

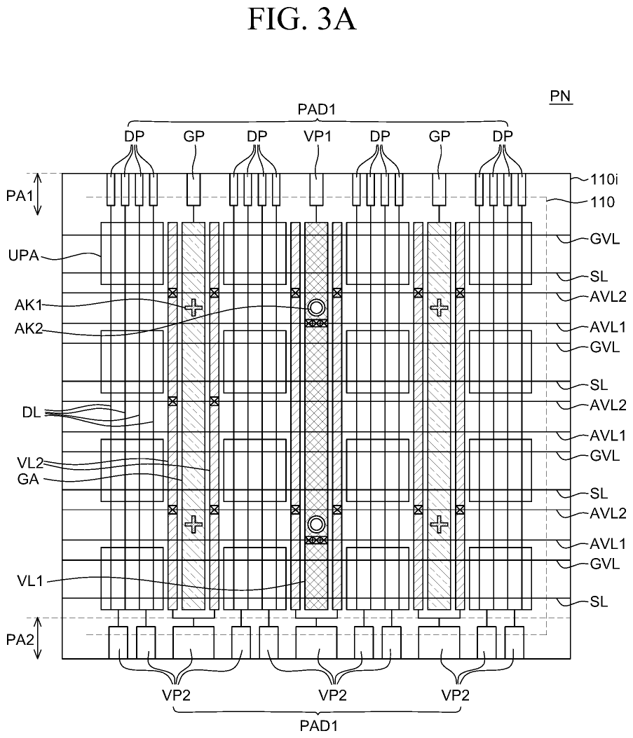

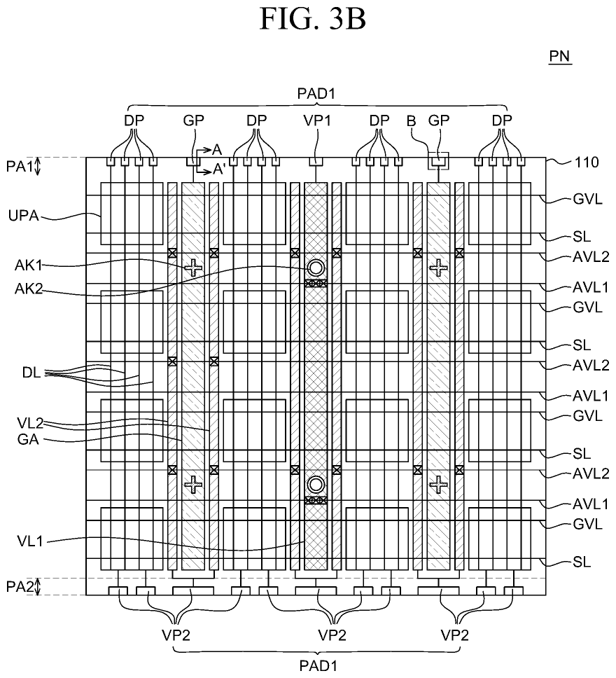

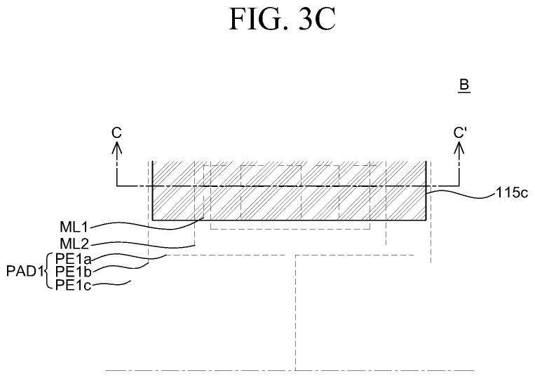

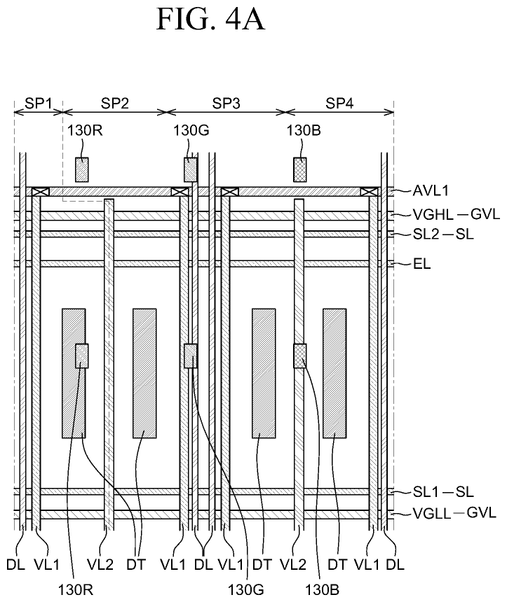

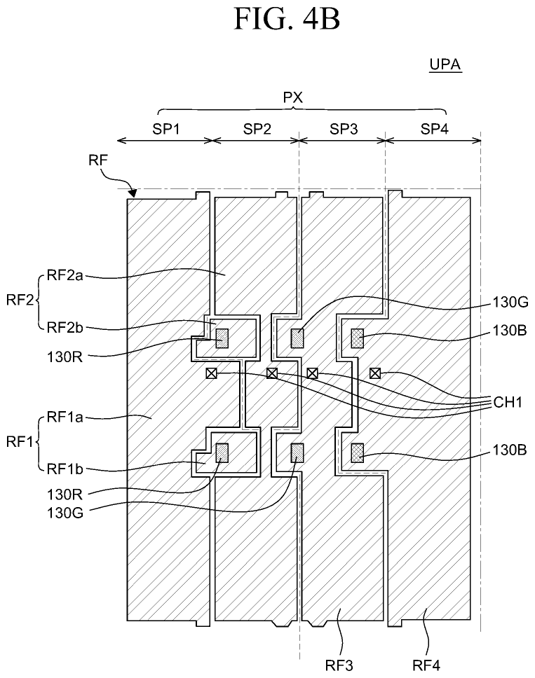

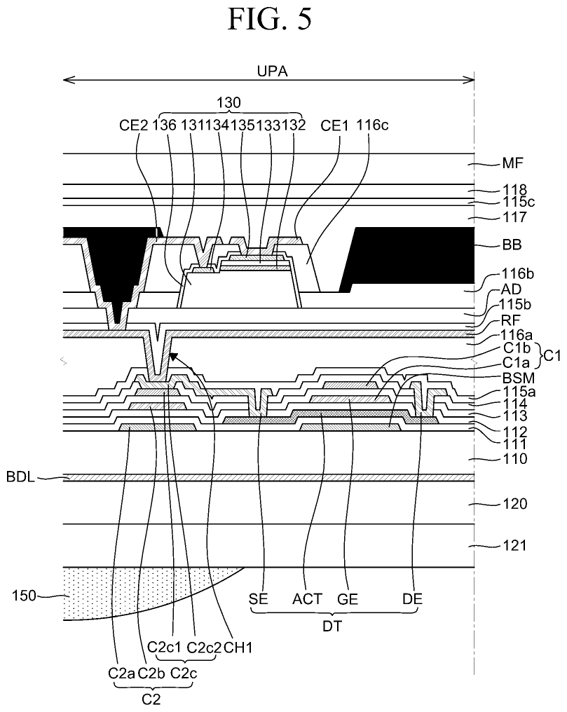

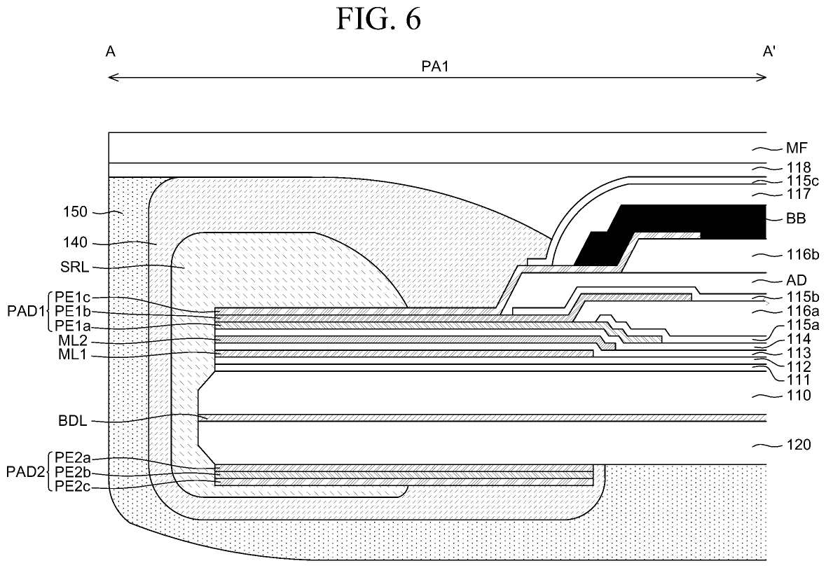

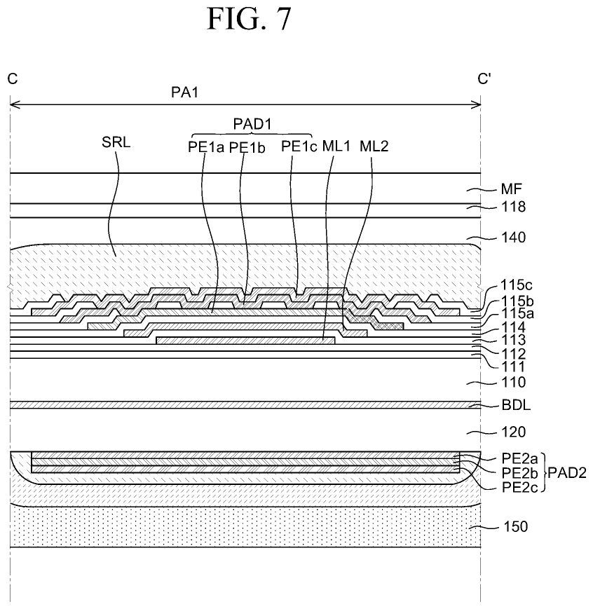

FIG. 3A is a plan view of a display panel before grinding a display device according to an exemplary aspect of the present disclosure. FIG. 3B is a plan view of a display panel after grinding a display device according to an exemplary aspect of the present disclosure. FIG. 3C is an enlarged plan view of area B of FIG. 3B. FIGS. 4A and 4B are plan views illustrating a pixel area of a display device according to an exemplary aspect of the present disclosure. FIG. 5 is a cross-sectional view of a pixel area of a display device according to an exemplary aspect of the present disclosure. FIG. 6 is a cross-sectional view taken along A-A′ of FIG. 3B. FIG. 7 is a cross-sectional view taken along C-C′ of FIG. 3B. For the convenience of description, in FIG. 4A, only the plurality of light emitting diodes 130R, 130G, and 130B, a driving transistor DT of the pixel circuit, and a plurality of wiring lines are illustrated and in FIG. 4B, only a plurality of reflection plates RF and a plurality of light emitting diodes 130R, 130G, and 130B, are illustrated. FIGS. 6 and 7 are cross-sectional views for explaining a first pad area PA1 of the display device 100 according to an exemplary aspect of the present disclosure.

First, referring to FIGS. 3A to 7, the display panel PN includes a first substrate 110. The first substrate 110 is a substrate which supports components disposed above the display device 100 and may be an insulating substrate. A plurality of pixels PX are formed on the first substrate 110 to display images. For example, the first substrate 110 may be formed of glass or resin. Further, the first substrate 110 may include polymer or plastic. In some exemplary aspects, the first substrate 110 may be formed of a plastic material having flexibility.

Referring to FIGS. 3A to 3C, in the first substrate 110, a plurality of pixel areas UPA, a plurality of gate driving areas GA, and a plurality of pad areas PA1 and PA2 are disposed. Among them, the plurality of pixel areas UPA and the plurality of gate driving areas GA may be included in the active area AA of the display panel PN.

First, the plurality of pixel areas UPA are areas in which the plurality of pixels PX are disposed. The plurality of pixel areas UPA may be disposed by forming a plurality of rows and a plurality of columns. Each of the plurality of pixels PX disposed in the plurality of pixel areas UPA includes a plurality of sub pixels SP. Each of the plurality of sub pixels SP includes a light emitting diode 130 and a pixel circuit to independently emit light.

The plurality of gate driving areas GA is areas where gate drivers GD are disposed. The gate driver GD may be mounted in the active area AA in a gate in active area (GIA) manner. For example, the gate driving area GA may be formed along a row direction and/or column direction between the plurality of pixel areas UPA. The gate driver GD formed in the gate driving area GA may supply the scan signal to the plurality of scan lines SL.

The gate driver GD disposed in the gate driving area GA may include a circuit for outputting a scan signal. The gate driver may include, for example, a plurality of transistors and/or capacitors. Here, active layers of the plurality of transistors may be formed of a semiconductor material, such as an oxide semiconductor, amorphous silicon, and polysilicon, but are not limited thereto. The active layers of the plurality of transistors may be formed of the same material or different materials from each other. Further, the active layers of the transistors of the gate driver and the active layers of various transistors of the pixel circuit may be formed of the same material or formed of different materials from each other.

The plurality of pad areas PA1 and PA2 are disposed in the non-active area NA at an upper portion and a lower portion of the display panel PN. The plurality of pad areas PA1 and PA2 are areas in which a plurality of first pad electrodes PAD1 are disposed. The plurality of first pad electrodes PAD1 may transmit various signals to various wiring lines extending in a column direction in the active area AA. For example, the plurality of first pad electrodes PAD1 include a data pad DP, a gate pad GP, a high potential power pad VP1, and a low potential power pad VP2. The data pad DP transmits a data voltage to the data line DL and the gate pad GP transmits a clock signal, a start signal, a gate low voltage, a gate high voltage, and the like for driving the gate driver GD to the gate driver GD. The high potential power pad VP1 transmits a high potential power voltage to the high potential power line VL1 and the low potential power pad VP2 transmits a low potential power voltage to the low potential power line VL2.

The plurality of pad areas PA1 and PA2 include a first pad area PA1 disposed at an upper periphery of the display panel PN and a second pad area PA2 located at a lower edge of the display panel PN. In the first pad area PA1 and the second pad area PA2, the plurality of first pad areas PAD1 are disposed to transmit a signal to the plurality of sub pixels SP. In the first pad area PA1 and the second pad area PA2, different types of first pad electrodes PAD1 may be disposed. For example, among the plurality of first pad electrodes PAD1, the data pad DP, the gate pad GP, and the high potential power pad VP1 are disposed in the first pad area PA1, and the low potential power pad VP2 may be disposed in the second pad area PA2.

Each of plurality of first pad electrodes PAD1 may be formed to have different sizes. For example, the plurality of data pads DP which are connected to the plurality of data lines DL one to one may have a narrower width and the high potential power pad VP1, the low potential power pad VP2, and the gate pad GP may have a larger width. However, widths of the data pad DP, the gate pad GP, the high potential power pad VP1, and the low potential power pad VP2 illustrated in FIGS. 3A to 3C are illustrative so that the first pad electrode PAD1 may be configured in various sizes, but is not limited thereto.

To reduce the bezel of the display panel PN, a periphery of the display panel PN may be cut to be removed. For example, as illustrated in FIG. 3A, the plurality of pixels PX, the plurality of wiring lines, and the plurality of first pad electrodes PAD1 are formed on an initial first substrate 110i and as illustrated in FIG. 3B, an edge part of the initial first substrate 110i is ground to reduce the bezel area. During the grinding process, a part of the initial first substrate 110i is removed to form a first substrate 110 with a smaller size. Parts of the plurality of first pad electrodes PAD1 and wiring lines disposed at the periphery of the first substrate 110 may be removed. Accordingly, only a part of the plurality of first pad electrodes PAD1 may remain on the first substrate 110.

Next, the plurality of data lines DL which extend in a column direction from the plurality of first pad electrodes PAD1 are disposed on the first substrate 110 of the display panel PN. The plurality of data lines DL may extend from the plurality of data pads DP of the first pad area PA1 toward the plurality of pixel areas UPA. The plurality of data lines DL may extend in a column direction and overlap the plurality of pixel areas UPA. Therefore, the plurality of data lines DL may transmit the data voltage to the pixel circuit of each of the plurality of sub pixels SP.

The plurality of high potential power lines VL1 extending in the column direction are disposed on the first substrate 110 of the display panel PN. Some of the plurality of high potential power lines VL1 extend from the high potential power pad VP1 of the first pad area PA1 to the plurality of pixel areas UPA to transmit the high potential power voltage to the light emitting diodes 130 of the plurality of sub pixels SP, respectively. The others of the plurality of high potential power lines VL1 may be electrically connected to the other high potential power line VL1 by means of an auxiliary high potential power line AVL1 to be described below. In FIGS. 3A and 3B, for the convenience of description, even though it is illustrated that one high potential power line VL1 and one high potential power pad VP1 are disposed, a plurality of high potential power lines VL1 and high potential power pads VP1 may be disposed.

Referring to FIG. 3C, a plurality of contact holes are formed in one first pad electrode PAD1.

Each of the plurality of first pad electrodes PAD1 may be configured by a plurality of conductive layers. For example, each of the plurality of first pad electrodes PAD1 includes a first conductive layer PE1a, a second conductive layer PE1b disposed on the first conductive layer PE1a, and a third conductive layer PE1c disposed on the second conductive layer PE1b. The second conductive layer PE1b of one first pad electrode PAD1 is electrically connected to the first conductive layer PE1a through a plurality of contact holes formed in the first passivation layer 115a. The plurality of contact holes are disposed in the first passivation layer 115a on the first conductive layer PE1a of each of the plurality of first pad electrodes PAD1. The second conductive layer PE1b and the first conductive layer PE1a are disposed to be in contact with each other by a plurality of contact surfaces thereof in the contact holes of the first passivation layer 115a. For example, the first conductive layer PE1a and the second conductive layer PE1b of the first pad electrode PAD1 may be electrically connected to each other by the plurality of contact holes.

The plurality of low potential power lines VL2 extending in the column direction are disposed on the first substrate 110 of the display panel PN. At least some of the plurality of low potential power lines VL2 extend from the low potential power pad VP2 of the second pad area PA2 to the plurality of pixel areas UPA to transmit the low potential power voltage to the pixel circuit of each of the plurality of sub pixels SP. The others of the plurality of low potential power lines VL2 may be electrically connected to the other low potential power line VL2 by means of an auxiliary low potential power line AVL2 to be described below.

The plurality of scan lines SL extending in the row direction are disposed on the first substrate 110 of the display panel PN. The plurality of scan lines SL extending in the row direction and may be disposed across the plurality of pixel areas UPA and the plurality of gate driving areas GA. The plurality of scan lines SL may transmit the scan signal from the gate driver GD to the pixel circuits of the plurality of sub pixels SP.

A plurality of auxiliary high potential power lines AVL1 extending in the row direction are disposed on the first substrate 110 of the display panel PN. The plurality of auxiliary high potential power lines AVL1 may be disposed in an area between the plurality of pixel areas UPA. The plurality of auxiliary high potential power lines AVL1 extending in the row direction are electrically connected to the plurality of high potential power lines VL1 extending in the column direction through a contact hole and may form a mesh structure. Therefore, the plurality of auxiliary high potential power lines AVL1 and the plurality of high potential power lines VL1 are configured to form a mesh structure to minimize voltage drop and voltage deviation.

A plurality of auxiliary low potential power lines AVL2 extending in the row direction are disposed on the first substrate 110 of the display panel PN. The plurality of auxiliary low potential power lines AVL2 may be disposed in an area between the plurality of pixel areas UPA. The plurality of auxiliary low potential power lines AVL2 extending in the row direction are electrically connected to the plurality of low potential power lines VL2 extending in the column direction through a contact hole to form a mesh structure. Therefore, the plurality of auxiliary low potential power lines AVL2 and the plurality of low potential power lines VL2 are configured to form a mesh structure to reduce a resistance of the wiring line and minimize voltage deviation.

Referring to FIGS. 3A to 4A, the plurality of gate driving lines extending in the row direction and the column direction are disposed on the first substrate 110 of the display panel PN. Some of the plurality of gate driving lines extend from the gate pad GP of the first pad area PA1 to the gate driving area GA to transmit a signal to the gate driver GD. The others of the plurality of gate driving lines extend in the row direction and may transmit the signal to the gate drivers GD of the plurality of gate driving areas GA. Therefore, various signals are transmitted from the gate driving line to the gate driver GD to drive the gate driver GD.

The plurality of gate driving lines may include wiring lines which transmit a clock signal, a start signal, a gate high voltage, a gate low voltage, and the like to the gate driver GD. Therefore, various signals are transmitted from the gate driving line to the gate driver GD to drive the gate driver GD.

For example, referring to FIG. 4A, the plurality of gate driving lines may include a gate power line GVL which transmits a power voltage to the gate driver GD of the gate driving area GA. The plurality of gate power lines GVL include a first gate power line VGHL which transmits a gate high voltage to the gate driver GD and a second gate power line VGLL which transmits a gate low voltage to the gate driver GD.

A plurality of alignment keys AK1 and AK2 are disposed in an area between the plurality of pixel areas UPA in the display panel PN. The plurality of alignment keys AK1 and AK2 are used for alignment during the manufacturing process of the display panel PN. The plurality of alignment keys AK1 and AK2 include a first alignment key AK1 and a second alignment key AK2.

The first alignment key AK1 may be disposed in the gate driving area GA between the plurality of pixel areas UPA. The first alignment key AK1 may be used to inspect an alignment position of the plurality of light emitting diodes 130. For example, the first alignment key AK1 may have a cross shape, but is not limited thereto.

The second alignment key AK2 may be disposed to overlap the high potential power line VL1 between the plurality of pixel areas UPA. In the high potential power line VL1, a hole overlapping the second alignment key AK2 is formed to divide the second alignment key AK2 and the high potential power line VL1. The second alignment key AK2 may be used to align the display panel PN and a donor. The display panel PN and the donor are aligned using the second alignment key AK2 and the plurality of light emitting diodes 130 of the donor may be transferred onto the display panel PN. For example, the second alignment key AK2 may have a circular ring shape, but is not limited thereto.

Hereinafter, the plurality of sub pixels SP of the pixel area UPA will be described in more detail with reference to FIGS. 4A to 5.

Referring to FIGS. 4A and 4B, in one pixel area UPA, a plurality of sub pixels SP which forms one pixel PX are disposed. For example, the plurality of sub pixels SP may include a first sub pixel SP1, a second sub pixel SP2, a third sub pixel SP3, and a fourth sub pixel SP4 which emit different color light. For example, the first sub pixel SP1 and the second sub pixel SP2 may be red sub pixels, the third sub pixel SP3 may be a green sub pixel, and the fourth sub pixel SP4 may be a blue sub pixel, but it is not limited thereto.

Hereinafter, the description will be made by assuming that one pixel PX includes one first sub pixel SP1, one second sub pixel SP2, one third sub pixel SP3, and one fourth sub pixel SP4, for example, two red sub pixels, one green sub pixel, and one blue sub pixel. However, the configuration of the pixel PX is not limited thereto.

Referring to FIG. 4A, as described above, a plurality of wiring lines which supply various signals to the plurality of sub pixels SP are disposed in the plurality of pixel areas UPA of the first substrate 110. For example, the plurality of data lines DL, the plurality of high potential power lines VL1, and the plurality of low potential power lines VL2 extending in the column direction may be disposed on the first substrate 110. For example, the plurality of emission control signal lines EL, the plurality of auxiliary high potential power lines AVL1, the plurality of auxiliary low potential power lines AVL2, the plurality of first scan lines SL1, and the plurality of second scan lines SL2 extending in the row direction may be disposed on the first substrate 110. The high potential power line VL1 extending in the column direction may be electrically connected to the auxiliary high potential power line AVL1 extending in the row direction through a contact hole. The emission control signal line EL transmits an emission control signal to the pixel circuits of the plurality of sub pixels SP to control emission timings of the plurality of sub pixels SP.

Some gate power lines GVL which transmit a signal to each of the plurality of gate drivers GD disposed to be spaced apart from each other with the pixel area UPA therebetween may be disposed across the pixel area UPA while extending to the row direction. For example, a first gate power line VGHL which supplies a gate high voltage to the gate driver GD and a second gate power line VGLL which supplies a gate low voltage to the gate driver GD may be disposed across the pixel area UPA.

Even though it is illustrated that the plurality of scan lines SL include a first scan line SL1 and a second scan line SL2, the configuration of the plurality of scan lines SL may vary depending on the pixel circuit configuration of the sub pixel SP, and is not limited thereto.

The pixel circuit for driving the light emitting diode 130 is disposed in each of the plurality of sub pixels SP on the first substrate 110. The pixel circuit may include a plurality of thin film transistors and a plurality of capacitors. In FIGS. 4A and 5, for the convenience of description, only a driving transistor DT, a first capacitor C1, and a second capacitor C2, among configurations of the pixel circuit are illustrated. However, the pixel circuit may further include a switching transistor, a sensing transistor, an emission control transistor, and the like, and is not limited thereto.

First, a light shielding layer BSM is disposed on the first substrate 110. The light shielding layer BSM blocks light which is incident to an active layer of the plurality of transistors to minimize a leakage current. For example, the light shielding layer BSM is disposed below the active layer ACT of the driving transistor DT to block light incident onto the active layer ACT. If light is irradiated onto the active layer ACT, a leakage current is generated, which deteriorates the reliability of the transistor. Accordingly, the light shielding layer BSM which blocks the light is disposed on the first substrate 110 to improve the reliability of the driving transistor DT. The light shielding layer BSM may be configured by an opaque conductive material such as copper (Cu), aluminum (Al), molybdenum (Mo), nickel (Ni), titanium (Ti), and chrome (Cr), or an alloy thereof, but is not limited thereto.

A buffer layer 111 is disposed on the light shielding layer BSM. The buffer layer 111 may reduce permeation of moisture or impurities through the first substrate 110. For example, the buffer layer 111 may be configured by a single layer or a double layer of silicon oxide (SiOx) or silicon nitride (SiNx), but is not limited thereto. However, the buffer layer 111 may be omitted depending on a type of the first substrate 110 or a type of the thin film transistor, but is not limited thereto.

An additional buffer layer may be disposed between the first substrate 110 and the light shielding layer BSM. The additional buffer layer may be configured by a single layer or a double layer of silicon oxide (SiOx) or silicon nitride (SiNx) to reduce permeation of moisture or impurities through the first substrate 110, like the buffer layer 111 described above.

A driving transistor DT including an active layer ACT, a gate electrode GE, a source electrode SE, and a drain electrode DE is disposed on the buffer layer 111.

First, the active layer ACT of the driving transistor DT is disposed on the buffer layer 111. The active layer ACT may be formed of a semiconductor material such as an oxide semiconductor, amorphous silicon, and polysilicon, but is not limited thereto. Other transistors, such as a switching transistor, a sensing transistor, and an emission control transistor, other than the driving transistor DT, may be further disposed on the first substrate 110. The active layers of the transistors may be also formed of a semiconductor material, such as an oxide semiconductor, amorphous silicon, and polysilicon, but are not limited thereto. The active layer of the transistor included in the pixel circuit, such as the driving transistor DT, the switching transistor, the sensing transistor, and the emission control transistor, may be formed of the same material, or formed of different materials.

The gate insulating layer 112 is disposed on the active layer ACT. The gate insulating layer 112 is an insulating layer which electrically insulates the active layer ACT from the gate electrode GE and may be configured by a single layer or a double layer of silicon oxide (SiOx) or silicon nitride (SiNx), but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), and chrome (Cr), or an alloy thereof, but is not limited thereto.

A first interlayer insulating layer 113 and a second interlayer insulating layer 114 are disposed on the gate electrode GE. In the first interlayer insulating layer 113 and the second interlayer insulating layer 114, contact holes through which each of the source electrode SE and the drain electrode DE is connected to the active layer are formed. The first interlayer insulating layer 113 and the second interlayer insulating layer 114 are insulating layers which protect components therebelow and may be configured by single layers or double layers of silicon oxide (SiOx) or silicon nitride (SiNx), but are not limited thereto.

The source electrode SE and the drain electrode DE which are electrically connected to the active layer ACT are disposed on the second interlayer insulating layer 114. The source electrode SE is connected to the second capacitor C2 and the first electrode 134 of the light emitting diode 130 and the drain electrode DE is connected to the other configuration of the pixel circuit. The source electrode SE and the drain electrode DE may be configured by a conductive material, such as copper (Cu), aluminum (Al), molybdenum (Mo), nickel (Ni), titanium (Ti), and chrome (Cr), or an alloy thereof, but are not limited thereto.

Next, the first capacitor C1 is disposed on the gate insulating layer 112. The first capacitor C1 includes a 1-1-th capacitor electrode C1a and a 1-2-th capacitor electrode C1b.

First, the 1-1-th capacitor electrode C1a is disposed on the gate insulating layer 112. The 1-1-th capacitor electrode C1a may be integrally formed with the gate electrode GE of the driving transistor DT.

The 1-2-th capacitor electrode C1b is disposed on the first interlayer insulating layer 113. The 1-2-th capacitor electrode C1b is disposed to overlap the 1-1-th capacitor electrode C1a with the first interlayer insulating layer 113 therebetween.

Therefore, the first capacitor C1 is connected to the gate electrode GE of the driving transistor DT to maintain a voltage of the gate electrode GE of the driving transistor DT for a predetermined period.

Next, the second capacitor C2 is disposed on the first substrate 110. The second capacitor C2 includes a 2-1-th capacitor electrode C2a, a 2-2-th capacitor electrode C2b, and a 2-3-th capacitor electrode C2c. The second capacitor C2 includes the 2-1-th capacitor electrode C2a which is a lower capacitor electrode, the 2-2-th capacitor electrode C2b which is an intermediate capacitor electrode, and the 2-3-th capacitor electrode C2c which is an upper capacitor electrode.

The 2-1-th capacitor electrode C2a is disposed on the first substrate 110. The 2-1-th capacitor electrode C2a is disposed on the same layer as the light shielding layer BSM and may be formed of the same material.

The 2-2-th capacitor electrode C2b is disposed on the buffer layer 111 and the gate insulating layer 112. The 2-2-th capacitor electrode C2b is disposed on the same layer as the gate electrode GE and may be formed of the same material.

The 2-3-th capacitor electrode C2c is disposed on the first interlayer insulating layer 113. The 2-3-th capacitor electrode C2c may be configured by a first layer C2c1 and a second layer C2c2. The first layer C2c1 of the 2-3-th capacitor electrode C2c may be formed on the same layer as the 1-2-th capacitor electrode C1b with the same material. The first layer C2c1 may be disposed to overlap the 2-1-th capacitor electrode C2a and the 2-2-th capacitor electrode C2b with the first interlayer insulating layer 113 between the first layer C2c1 and the 2-2-th capacitor electrode C2b.

The second layer C2c2 of the 2-3-th capacitor electrode C2c is disposed on the second interlayer insulating layer 114. The second layer C2c2 is a part extending from the source electrode SE of the driving transistor DT and may be connected to the first layer C2c1 through the contact hole of the second interlayer insulating layer 114.

Accordingly, the second capacitor C2 is electrically connected between the source electrode SE of the driving transistor DT and the light emitting diode 130 to increase capacitance inherent in the light emitting diode 130 and allow the light emitting diode 130 to emit light with a higher luminance

A first passivation layer 115a is disposed on the driving transistor DT, the first capacitor C1, and the second capacitor C2. The first passivation layer 115a is an insulating layer for protecting a configuration below the first passivation layer 115a. The first passivation layer 115a may be disposed on the entire first substrate 110. For example, the first passivation layer 115a may cover the plurality of driving transistors DT to protect the driving transistors DT.

The first passivation layer 115a may be formed of an inorganic material, for example, may be formed of silicon oxide SiOx and silicon nitride SiNx, but is not limited thereto.

A first planarization layer 116a is disposed on the first passivation layer 115a. The first planarization layer 116a may be disposed to cover the first passivation layer 115a. The first planarization layer 116a may planarize an upper portion of the pixel circuit including the driving transistor DT. The first planarization layer 116a may be configured by a single layer or a double layer, and for example, configured by benzocyclobutene or an acrylic organic material, but is not limited thereto.

Referring to FIGS. 4B and 5 together, a plurality of reflection plates RF are disposed on the first planarization layer 116a. The reflection plates RF are disposed to overlap the plurality of light emitting diodes 130. The reflection plate RF is a configuration which reflects light emitted from the plurality of light emitting diodes 130 above the first substrate 110 and may be formed with a shape corresponding to each of the plurality of sub pixels SP. One reflection plate RF may be disposed to cover the most area of one sub pixel SP.

The reflection plate RF may reflect the light emitted from the light emitting diode 130 and may be also used as an electrode which electrically connects the light emitting diode 130 and the pixel circuit. Therefore, the reflection plate RF may include various conductive layers in consideration of a light reflection efficiency and a resistance. For example, the reflection plate RF may use an opaque conductive layer such as silver (Ag), aluminum (Al), molybdenum (Mo), and titanium (Ti), or an alloy thereof and a transparent conductive layer such as indium tin oxide together, but the structure of the reflection plate RF is not limited thereto.

The reflection plate RF includes a first reflection plate RF1 corresponding to the first sub pixel SP1, a second reflection plate RF2 corresponding to the second sub pixel SP2, a third reflection plate RF3 corresponding to the third sub pixel SP3, and a fourth reflection plate RF4 corresponding to the fourth sub pixel SP4.

The first reflection plate RF1 includes a 1-1-th reflection plate RF1a overlapping most of the first sub pixel SP1 and a 1-2-th reflection plate RF1b overlapping the red light emitting diode 130R of the first sub pixel SP1. A 1-1-th reflection plate RF1a may reflect light emitted from the red light emitting diode 130R above the red light emitting diode 130R. The 1-1-th reflection plate RF1a may be electrically connected to the source electrode SE of the driving transistor DT and the second capacitor C2 through a first contact hole CH1 of the first planarization layer 116a and the first passivation layer 115a. Therefore, the 1-1-th reflection plate RF1a may electrically connect the driving transistor DT and the first electrode 134 of the red light emitting diode 130R. The 1-2-th reflection plate RF1b may reflect light emitted from the red light emitting diode 130R above the red light emitting diode 130R. The 1-2-th reflection plate RF1b may serve as an electrode which electrically connects the second electrode 135 of the red light emitting diode 130R and the high potential power line VL1.

The second reflection plate RF2 includes a 2-1-th reflection plate RF2a overlapping most of the second sub pixel SP2 and a 2-2-th reflection plate RF2b overlapping the red light emitting diode 130R of the second sub pixel SP2. The 2-1-th reflection plate RF2a may reflect light emitted from the red light emitting diode 130R above the red light emitting diode 130R. The 2-1-th reflection plate RF2a is electrically connected to the source electrode SE of the driving transistor DT and the second capacitor C2 through the first contact hole CH1 to transmit a driving current from the driving transistor DT to the first electrode 134 of the red light emitting diode 130R. The 2-2-th reflection plate RF2b may be used as an electrode which reflects the light emitted from the red light emitting diode 130R above the red light emitting diode 130R and electrically connects the second electrode 135 of the red light emitting diode 130R to the high potential power line VL1.

The third reflection plate RF3 may be formed as one third reflection plate RF3 which overlaps the entire third sub pixel SP3. The third reflection plate RF3 may reflect light emitted from the green light emitting diode 130G of the third sub pixel SP3 above the green light emitting diode 130G. The third reflection plate RF3 is electrically connected to the source electrode SE of the driving transistor DT and the second capacitor C2 through the first contact hole CH1 to transmit a driving current from the driving transistor DT to the first electrode 134 of the green light emitting diode 130G.

The fourth reflection plate RF4 may be formed as one fourth reflection plate RF4 which overlaps the entire fourth sub pixel SP4. The fourth reflection plate RF4 may reflect light emitted from the blue light emitting diode 130B of the fourth sub pixel SP4 above the blue light emitting diode 130B. The fourth reflection plate RF4 is electrically connected to the source electrode SE of the driving transistor DT and the second capacitor C2 through the first contact hole CH1 to transmit a driving current from the driving transistor DT to the first electrode 134 of the blue light emitting diode 130B.

Even though it has been described that the first sub pixel SP1 and the second sub pixel SP2 are formed with two reflection plates RF and the third sub pixel SP3 and the fourth sub pixel SP4 are formed with one reflection plate RF, the reflection plate RF may be designed in various manners. For example, only one reflection plate RF may be disposed in all the plurality of sub pixels SP, like the third sub pixel SP3 and the fourth sub pixel SP4 or a plurality of reflection plates RF may be disposed in all the sub pixels like the first sub pixel SP1 and the second sub pixel SP2, but the reflection plate is not limited thereto.

Further, it has been described that the red light emitting diode 130R of each of the first sub pixel SP1 and the second sub pixel SP2 is electrically connected to the high potential power line VL1 through the 1-2-th reflection plate RF1b and the 2-2-th reflection plate RF2b. However, all the red light emitting diode 130R, the green light emitting diode 130G, and the blue light emitting diode 130B may be separately connected to the high potential power line VL1 without the reflection plate RF, but are not limited thereto.

Referring to FIG. 5, the second passivation layer 115b is disposed on the plurality of reflection plates RF. The second passivation layer 115b is an insulating layer for protecting a configuration below the second passivation layer 115b. The second passivation layer 115b may be disposed on the entire first substrate 110. For example, the second passivation layer may be disposed to cover the plurality of reflection plates RF and the first planarization layer 116a.

The second passivation layer 115b may be formed of an inorganic material. For example, the second passivation layer 115b may be configured by a single layer or a double layer of silicon oxide (SiOx) or silicon nitride (SiNx), but is not limited thereto.

An adhesive layer AD is disposed on the second passivation layer 115b. The adhesive layer AD is formed on the entire surface of the first substrate 110 to fix the light emitting diode 130 disposed on the adhesive layer AD. The adhesive layer AD may be formed of a photo curable adhesive material which is cured by light. For example, the adhesive layer AD may be formed of an acrylic material including a photoresist, but is not limited thereto. The adhesive layer AD may be formed on the entire surface of the first substrate 110 excluding a part of the pad areas PA1 and PA2 in which the first pad electrode PAD1 is disposed.

The plurality of light emitting diodes 130 are disposed in each of the plurality of sub pixels SP on the adhesive layer AD. The light emitting diode 130 is an element which emits light by a current and may include a red light emitting diode 130R which emits red light, a green light emitting diode 130G which emits green light, and a blue light emitting diode 130B which emits blue light and may implement light with various colors including white by a combination thereof. For example, the light emitting diode 130 may be a light emitting diode (LED) or a micro LED, but is not limited thereto.

One red light emitting diode 130R is disposed in each of the first sub pixel SP1 and the second sub pixel SP2, one pair of green light emitting diodes 130G is disposed in the third sub pixel SP3, and one pair of blue light emitting diodes 130B is disposed in the fourth sub pixel SP4. For example, two red light emitting diodes 130R, two green light emitting diodes 130G, and two blue light emitting diodes 130B may be disposed in one pixel PX. Each of the red light emitting diodes 130R is connected to the driving transistor DT of each of the first sub pixel SP1 and the second sub pixel SP2 to be individually driven. In contrast, one pair of green light emitting diodes 130G of the third sub pixel SP3 and one pair of blue light emitting diodes 130B of the fourth sub pixel SP4 are connected to one driving transistor DT in parallel to be driven.

The plurality of light emitting diodes 130 are disposed on the adhesive layer AD. The plurality of light emitting diodes 130 include a first semiconductor layer 131, an emission layer 132, a second semiconductor layer 133, a first electrode 134, and a second electrode 135.

The first semiconductor layer 131 is disposed on the adhesive layer AD and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers doped with n-type and p-type impurities into a material such as gallium nitride (GaN), indium aluminum phosphide (InAlP), and gallium arsenide (GaAs). The p-type impurity may be magnesium (Mg), zinc (Zn), beryllium (Be), and the like, and the n-type impurity may be silicon (Si), germanium, tin (Sn), and the like, but are not limited thereto.

The emission layer 132 is disposed between the first semiconductor layer 131 and the second semiconductor layer 133. The emission layer 132 is supplied with holes and electrons from the first semiconductor layer 131 and the second semiconductor layer 133 to emit light. The emission layer 132 may be formed by a single layer or a multi-quantum well (MQW) structure, and for example, may be formed of indium gallium nitride (InGaN) or gallium nitride (GaN), but is not limited thereto.

The first electrode 134 is disposed on the first semiconductor layer 131. The first electrode 134 is an electrode which electrically connects the driving transistor DT and the first semiconductor layer 131. In this case, the first semiconductor layer 131 is a semiconductor layer doped with an n-type impurity and the first electrode 134 may be a cathode. The first electrode 134 may be disposed on a top surface of the first semiconductor layer 131 which is exposed from the emission layer 132 and the second semiconductor layer 133. The first electrode 134 may be configured by a conductive material, for example, a transparent conductive material, such as indium tin oxide (ITO) and indium zinc oxide (IZO) or an opaque conductive material, such as titanium (Ti), gold (Au), silver (Ag), and copper (Cu) or an alloy thereof, but is not limited thereto.

The second electrode 135 is disposed on the second semiconductor layer 133. The second electrode 135 may be disposed on the top surface of the second semiconductor layer 133. The second electrode 135 is an electrode which electrically connects the high potential power line and the second semiconductor layer 133. In this case, the second semiconductor layer 133 is a semiconductor layer doped with a p-type impurity and the second electrode 135 may be an anode. The second electrode 135 may be configured by a conductive material, for example, a transparent conductive material, such as indium tin oxide (ITO) and indium zinc oxide (IZO) or an opaque conductive material, such as titanium (Ti), gold (Au), silver (Ag), and copper (Cu) or an alloy thereof, but is not limited thereto.

Next, the encapsulation layer 136 which encloses the first semiconductor layer 131, the emission layer 132, the second semiconductor layer 133, the first electrode 134, and the second electrode 135 is disposed. The encapsulation layer 136 is formed of an insulating material to protect the first semiconductor layer 131, the emission layer 132, and the second semiconductor layer 133. In the encapsulation layer 136, a contact hole which exposes the first electrode 134 and the second electrode 135 is formed to electrically connect a first connection electrode CE1 and a second connection electrode CE2 to the first electrode 134 and the second electrode 135.

A part of the side surface of the first semiconductor layer 131 may be exposed from the encapsulation layer 136. The light emitting diode 130 manufactured on the wafer is separated from the wafer to be transferred onto the display panel PN. However, during the process of separating the light emitting diode 130 from the wafer, a part of the encapsulation layer 136 may be torn. For example, a part of the encapsulation layer 136 which is adjacent to a lower edge of the first semiconductor layer 131 of the light emitting diode 130 is torn during the process of separating the light emitting diode 130 from the wafer. Accordingly, a part of a lower side surface of the first semiconductor layer 131 may be exposed to the outside. However, even though the lower portion of the light emitting diode 130 is exposed from the encapsulation layer 136, the first connection electrode CE1 and the second connection electrode CE2 are formed after forming the second planarization layer 116b and the third planarization layer 116c which cover the side surface of the first semiconductor layer 131. Accordingly, a short circuit problem may be reduced.

Next, the second planarization layer 116b and the third planarization layer 116c are disposed on the adhesive layer AD and the light emitting diode 130.

The second planarization layer 116b overlaps a part of side surfaces of the plurality of light emitting diodes 130 to fix and protect the plurality of light emitting diodes 130. The second planarization layer 116b may be formed using a halftone mask. Therefore, the second planarization layer 116b may be formed to have a step.

For example, a part of the second planarization layer 116b which is relatively adjacent to the light emitting diode 130 may be formed to have a smaller thickness and a part which is farther from the light emitting diode 130 may be formed to have a larger thickness. A part of the second planarization layer 116b which is adjacent to the light emitting diode 130 may be disposed to enclose the light emitting diode 130 and also may be in contact with a side surface of the light emitting diode 130. Therefore, a torn part of the encapsulation layer 136 which protects a side surface of the first semiconductor layer 131 of the light emitting diode 130 during the process of separating the light emitting diode 130 from the wafer to be transferred onto the display panel PN may be covered by the second planarization layer 116b. By doing this, contact and short problems of the connection electrodes CE1 and CE2 and the first semiconductor layer 131 later may be suppressed.

The third planarization layer 116c may be formed to cover upper portions of the second planarization layer 116b and the light emitting diode 130 and a contact hole which exposes the first electrode 134 and the second electrode 135 of the light emitting diode 130 may be formed. The first electrode 134 and the second electrode 135 of the light emitting diode 130 are exposed from the third planarization layer 116c and the third planarization layer 116c is partially disposed in an area between the first electrode 134 and the second electrode 135 to reduce a short problem. The second planarization layer 116b and the third planarization layer 116c may be configured by a single layer or a double layer, and for example, may be formed of photoresist or an acrylic organic material, but is not limited thereto.

The third planarization layer 116c may cover only the light emitting diode 130 and an area adjacent to the light emitting diode 130. The third planarization layer 116c is disposed in an area of the sub pixel SP enclosed by the bank BB and may be disposed in an island shape. Therefore, the bank BB may be disposed in a part of the top surface of the second planarization layer 116b and the third planarization layer 116c may be disposed in the other part of the top surface of the second planarization layer 116b.

The first connection electrode CE1 and the second connection electrode CE2 are disposed on the third planarization layer 116c. The first connection electrode CE1 is an electrode which electrically connects the second electrode 135 of the light emitting diode 130 and the high potential power line VL1. The first connection electrode CE1 may be electrically connected to the second electrode 135 of the light emitting diode 130 through a contact hole formed in the third planarization layer 116c.

The second connection electrode CE2 is an electrode which electrically connects the first electrode 134 of the light emitting diode 130 and the driving transistor DT. The second connection electrode CE2 may be connected to the 1-1-th reflection plate RF1a, the 1-2-th reflection plate RF1b, the third reflection plate RF3, and the fourth reflection plate RF4 of each of the plurality of sub pixels SP through contact holes formed in the third planarization layer 116c, the second planarization layer 116b, the adhesive layer AD, and the second passivation layer 115b. At this time, the 1-1-th reflection plate RF1a, the 1-2-th reflection plate RF1b, the third reflection plate RF3, and the fourth reflection plate RF4 are also connected to the source electrode SE of the driving transistor DT so that the source electrode SE of the driving transistor DT and the first electrode 134 of the light emitting diode 130 may be electrically connected to each other.

In the drawing, it is illustrated that the first electrode 134, the second connection electrode CE2, and the reflection plate RF are electrically connected to the source electrode SE of the driving transistor DT. In another example, the first electrode 134, the second connection electrode CE2, and the reflection plate RF may be connected to the drain electrode DE of the driving transistor DT, but it is not limited thereto.

A bank BB is disposed on the second planarization layer 116b exposed from the first connection electrode CE1, the second connection electrode CE2, and the third planarization layer 116c. The bank BB may be disposed to be spaced apart from the light emitting diode 130 with a predetermined interval and overlap at least partially the reflection plate RF. For example, the bank BB may cover a part of the second connection electrode CE2 formed in the contact holes of the third planarization layer 116c and the second planarization layer 116b. Further, for example, the bank BB may be disposed on the second planarization layer 116b with a predetermined interval from the light emitting diode 130. In this case, the bank BB and the third planarization layer 116c may be spaced apart from each other on a part of the second planarization layer 116b having a smaller thickness. That is, an end of the bank BB and an end of the third planarization layer 116c may be disposed on a part of the second planarization layer 116b having a smaller thickness formed by a halftone mask process to be spaced apart from each other.

The bank BB may be formed of an opaque material to reduce color mixture between the plurality of sub pixels SP and for example, may be formed of black resin, but is not limited thereto.

A thickness of a part of the bank BB which is formed in the contact holes of the third planarization layer 116c and the second planarization layer 116b to cover a part of the second connection electrode CE2 and a thickness of a part disposed on the second planarization layer 116b may be different from each other. For example, when the part of the bank BB covers a part of the second connection electrode CE2 formed in the contact holes of the third planarization layer 116c and the second planarization layer 116b, since the contact hole is formed from the second passivation layer 115b to the third planarization layer 116c, the bank BB may be disposed below the light emitting diode 130, that is, disposed to be lower than the light emitting diode 130. Therefore, the thickness of the part of the bank BB which covers a part of the second connection electrode CE2 formed in the contact holes of the third planarization layer 116c and the second planarization layer 116b may be larger than the thickness of a part of the bank BB disposed on the second planarization layer 116b.

A first protection layer 117 is disposed on the first connection electrode CE1, the second connection electrode CE2, and the bank BB. The first protection layer 117 extends to a part of the non-active area NA from the active area AA. Therefore, an end of the first protection layer 117 is disposed in the non-active area NA. The first protection layer 117 is a layer for protecting components below the first protection layer 117, and may be configured by a single layer or a double layer of translucent epoxy, silicon oxide (SiOx) or silicon nitride (SiNx), but is not limited thereto.

The third passivation layer 115c is disposed on the first protection layer 117. The third passivation layer 115c is a configuration for protecting the first protection layer 117 and is disposed to cover the first protection layer 117. The third passivation layer 115c may be disposed in the active area AA and a part of the non-active area NA extending from the active area AA. At this time, the third passivation layer 115c may be disposed to cover an end of the first protection layer 117 in the non-active area NA.

The third passivation layer 115c may be formed of an inorganic material. For example, the third passivation layer 115c may be configured by a single layer or a double layer of silicon oxide (SiOx) or silicon nitride (SiNx), but is not limited thereto.

Hereinafter, a non-active area NA and a plurality of pad areas PA1 and PA2 of a display device 100 according to an exemplary aspect of the present disclosure will be described in more detail with reference to FIGS. 6 and 7.

A plurality of first pad electrodes PAD1 are disposed in a first pad area PA1 and a second pad area PA2 of the first substrate 110. Each of the plurality of first pad electrodes PAD1 may be configured by a plurality of conductive layers. For example, each of the plurality of first pad electrodes PAD1 includes a first conductive layer PE1 a, a second conductive layer PE1b on the first conductive layer PE1a, and a third conductive layer PE1c on the second conductive layer PE1b.

First, the first conductive layer PE1 a is disposed on the second interlayer insulating layer 114. The first conductive layer PE1 a may be formed of the same material as the source electrode SE and the drain electrode DE. The first conductive layer PE1a may be configured by a conductive material such as copper (Cu), aluminum (Al), molybdenum (Mo), nickel (Ni), titanium (Ti), and chrome (Cr), or an alloy thereof, but is not limited thereto.

The first passivation layer 115a is disposed on the first conductive layer PE1 a. The first passivation layer 115a extends from the active area AA to the non-active area NA. Referring to FIG. 6, the first passivation layer 115a extends from the active area AA to cover an end portion of the first conductive layer PE1a. The first passivation layer 115a may be disposed to enclose the first conductive layer PE1a in the non-active area NA. Therefore, the first passivation layer 115a may be configured to protect the side surface of the first conductive layer PE1a during a subsequent process.

Even though it is not illustrated in the drawing, the first passivation layer 115a may extend to an area of the non-active area which does not overlap the plurality of first pad electrode PAD1, that is, between the plurality of first pad electrodes PAD1 and an outermost side of the top surface of the first substrate 110 in the left and right non-active areas NA of the first substrate 110.

The first planarization layer 116a is disposed on the first conductive layer PE1a and the first passivation layer 115a. Referring to FIG. 6, the first planarization layer 116a covers an end portion of the first passivation layer 115a in an area overlapping the plurality of first pad electrodes PAD1. Therefore, the first planarization layer 116a covers the first passivation layer 115a to suppress the damage that can be caused in the first passivation layer 115a which is an inorganic insulating layer during a subsequent process.

The first planarization layer 116a which extends from the active area AA to the plurality of pad areas PA1 and PA2 of the non-active area NA may be spaced apart from the plurality of first pad electrodes PAD1 in a peripheral portion of the plurality of first pad electrodes PAD1. For example, the first planarization layer 116a is spaced apart from the first pad electrode PAD1 between the plurality of first pad electrodes PAD1 of the first pad area PA1. Further, the first passivation layer 115a and the second passivation layer 115b are disposed to be in contact with each other in an area in which the plurality of first pad electrodes PAD1 and the first planarization layer 116a are spaced apart from each other. Therefore, the first planarization layer 116a is not in contact with the plurality of first pad electrodes PAD1 in the peripheral portion of the plurality of first pad electrodes PAD1 and the first planarization layer 116a is enclosed by the first passivation layer 115a and the second passivation layer 115b. Therefore, the permeation to the first pad electrode PAD1 due to the first planarization layer 116a which is an organic material may be minimized.

The second conductive layer PE1b is disposed on the first conductive layer PE1a, the first passivation layer 115a, and the first planarization layer 116a. The second conductive layer PE1b may be formed of the same material as the reflection plate RF. The second conductive layer PE1b may be formed of a conductive material and for example, may be configured by silver (Ag), aluminum (Al), molybdenum (Mo), or an alloy thereof, but is not limited thereto.

The second conductive layer PE1b of one first pad electrode PAD1 is electrically connected to the first conductive layer PE1a through a contact hole formed in the first passivation layer 115a. Referring to FIG. 7, a plurality of contact holes are disposed in the first passivation layer 115a on the first conductive layer PE1a of each of the plurality of first pad electrodes PAD1. The second conductive layer PE1b and the first conductive layer PE1a are disposed to be in contact with each other by a plurality of contact surfaces thereof in the plurality of contact holes of the first passivation layer 115a. That is, the first conductive layer PE1 a and the second conductive layer PE1b of the first pad electrode PAD1 may be electrically connected to each other by the plurality of contact holes.

At this time, the first planarization layer 116a may be disposed to be spaced apart from the contact surfaces of the first conductive layer PE1 a and the second conductive layer PE1b of the first pad electrode PAD1. Further, the adhesive layer AD to be described below may be also disposed to be spaced apart from the contact surface of the first conductive layer PE1 a and the second conductive layer PE1b of the first pad electrode PAD1. Therefore, an interlayer insulating layer, such as the first planarization layer 116a and the adhesive layer AD is not disposed on a contact surface of the first conductive layer PE1a and the second conductive layer PE1b. Further, the first conductive layer PE1 a and the second conductive layer PE1b of the first pad electrode PAD1 may be configured to be electrically connected by a plurality of contact holes.

The second passivation layer 115b is disposed on the second conductive layer PE1b and the first planarization layer 116a. The second passivation layer 115b extends from the active area AA to the non-active area NA to cover the first planarization layer 116a.

Referring to FIG. 6, the second passivation layer 115b extends from the active area AA to cover an end portion of the second conductive layer PE1b. The second passivation layer 115b may enclose the second conductive layer PE1b in the non-active area NA. Therefore, the second passivation layer 115b may be configured to protect the side surface of the second conductive layer PE1b during the subsequent process.

Referring to FIG. 7, the second passivation layer 115b is disposed to be in contact with the first passivation layer 115a in an area between the plurality of first pad electrodes PAD1. Therefore, the first passivation layer 115a and the second passivation layer 115b may be disposed to have a structure which seals the end of the first planarization layer 116a while being in contact with each other in the non-active area NA.

Even though it is not illustrated in the drawing, the second passivation layer 115b covers the first planarization layer 116a in an area between the plurality of first pad electrodes PAD1 and an end of the second passivation layer 115b is disposed on the first passivation layer 115a. That is, the first passivation layer 115a and the second passivation layer 115b may be disposed to be in contact with each other in an area between the plurality of first pad electrodes PAD1 which does not overlap the plurality of first pad electrodes PAD1.

The first passivation layer 115a and the second passivation layer 115b may be disposed to be in contact with each other also in left and right non-active areas NA of the first substrate 110. Therefore, the first passivation layer 115a and the second passivation layer 115b may be disposed to have a structure which seals the end of the first planarization layer 116a while being in contact with each other in all the non-active areas NA.

An adhesive layer AD is disposed on the second passivation layer 115b. The adhesive layer AD extends from the pixel area UPA to the non-active area NA. Referring to FIG. 6, the end of the adhesive layer AD is disposed at the outside from the end of the first planarization layer 116a in the non-active area NA. Therefore, the adhesive layer AD may alleviate the step formed by the first planarization layer 116a.

Referring to FIG. 6, the adhesive layer AD is disposed to cover an end of the second passivation layer 115b in an area overlapping the plurality of first pad electrodes PAD1. Further, the adhesive layer AD may be disposed to cover the end of the second passivation layer 115b, which is in an area between the plurality of first pad electrodes PAD1, in the non-active area NA. Therefore, the adhesive layer AD may protect the end of the second passivation layer 115b which is an inorganic material by covering the end of the second passivation layer 115b.

The second planarization layer 116b is disposed on the adhesive layer AD. The second planarization layer 116b may extend to a part of the non-active area NA from the active area AA or may be disposed only in the active area AA. At this time, the second planarization layer 116b may be disposed to partially have a lower thickness using a halftone mask. Therefore, the second planarization layer 116b may reduce steps of structures laminated in the vicinity of the plurality of first pad electrodes PAD1.

The third conductive layer PE1c is disposed on the second conductive layer PE1b, the adhesive layer AD, and the second planarization layer 116b. The third conductive layer PE1c is formed of the same material as the first connection electrode CE1 and the second connection electrode CE2. The third conductive layer PE1c may be formed of a transparent conductive material, such as indium tin oxide (ITO) and indium zinc oxide (IZO), but is not limited thereto.

A bank BB is disposed on the third conductive layer PE1c and the second planarization layer 116b. The bank BB extends to a part of the non-active area NA from the active area AA. The bank BB is disposed to enclose the plurality of light emitting diodes 130 and may be formed of an opaque material including a black material to reduce color mixture between the plurality of sub pixels SP and for example, may be formed of black resin, but is not limited thereto.

A first protection layer 117 is disposed on the third conductive layer PE1c, the second planarization layer 116b, and the bank BB. The first protection layer 117 extends to be disposed to a part of the non-active area NA from the active area AA. Therefore, an end of the first protection layer 117 may be disposed in the non-active area NA.

Referring to FIG. 6, an end of the bank BB is disposed in the inside from the end of the first protection layer 117. That is, the first protection layer 117 covers the bank BB to minimize the contamination of the other components of the display device 100 by the bank BB including the black material.

The third passivation layer 115c is disposed on the first protection layer 117. The third passivation layer 115c is disposed in the active area AA and a part of the non-active area NA extending from the active area AA. Referring to FIG. 6, the third passivation layer 115c may be disposed to cover an end of the first protection layer 117. Therefore, the third passivation layer 115c covers the first protection layer 117 to minimize the moisture permeation of the first protection layer 117.

Referring to FIG. 6, in the area overlapping the plurality of first pad electrodes PAD1, the end of the third passivation layer 115c is disposed to be in contact with the third conductive layer PE1c of the first pad electrode PAD1. Therefore, the third passivation layer 115c may more stably cover the end of the first protection layer 117 disposed on the third conductive layer PE1c. Referring to FIG. 7, the third passivation layer 115c is disposed to cover the end of the third conductive layer PE1c in an area between the plurality of first pad electrodes PAD1. Therefore, the third passivation layer 115c may be configured to protect the side surface of the third conductive layer PE1c during the subsequent process.

At this time, even though it is not illustrated in the drawings, a part of the plurality of conductive layers of the first pad electrode PAD1 is electrically connected to a plurality of wiring lines on the first substrate 110 to supply various signals to a plurality of wiring lines and a plurality of sub pixels SP. For example, the first conductive layer and/or the second conductive layer of the first pad electrode PAD1 is connected to the data line DL, the high potential power line VL1, the low potential power line VL2, and the like disposed in the active area AA to transmit signals thereto.

Referring to FIG. 6, the plurality of metal layers and inorganic insulating layers are disposed between the plurality of first pad electrodes PAD1 and the first substrate 110.

The plurality of metal layers include a first metal layer ML1 and a second metal layer ML2 on the first metal layer ML1. The first metal layer ML1 and the second metal layer ML2 may be disposed together with the plurality of insulating layers below the first pad electrodes PAD1, for example, the buffer layer 111, the gate insulating layer 112, the first interlayer insulating layer 113, and the second interlayer insulating layer 114. Therefore, the plurality of metal layers may be insulated from the plurality of first pad electrodes PAD1. The plurality of metal layers may not be electrically connected to the other components, but may be electrically floated.

Referring to FIG. 6, in the area overlapping the plurality of first pad electrodes PAD1, an end of the third passivation layer 115c is disposed at the inside from the end of the inorganic insulating layers. Even though it is not illustrated in the drawings, the end of the third passivation layer 115c may be disposed to overlap the ends of the inorganic insulating layers between the plurality of first pad electrodes PAD1. Further, also in the left and right non-active areas NA of the first substrate 110, the end of the third passivation layer 115c may be disposed to overlap the ends of the inorganic insulating layers, but is not limited thereto.

In the display device 100 according to the exemplary aspect of the present disclosure, the first metal layer ML1, the second metal layer ML2, and the plurality of insulating layers are disposed below the first pad electrode PAD1 to adjust a step of the first pad electrode PAD1. For example, the buffer layer 111, the gate insulating layer 112, the first metal layer ML1, the first interlayer insulating layer 113, and the second metal layer ML2 may be sequentially disposed between the first pad electrode PAD1 and the first substrate 110.

The first metal layer ML1 may be formed of the same conductive material as the gate electrode GE and the second metal layer ML2 may be formed of the same conductive material as a 1-2-th capacitor electrode C1b. However, the plurality of insulating layers, the first metal layer ML1, and the second metal layer ML2 below the first pad electrode PAD1 may be omitted depending on a design and are not limited thereto.

Referring to FIG. 6, a planar area of the plurality of metal layers may be smaller than a planar area of the first pad electrode PAD1, but is not limited thereto.

A second substrate 120 is disposed below the first substrate 110. The second substrate 120 is a substrate which supports components disposed below the display device 100 and may be an insulating substrate. For example, the second substrate 120 may be formed of glass or resin. Further, the second substrate 120 may include polymer or plastic. The second substrate 120 may be formed of the same material as the first substrate 110. In some exemplary aspects, the second substrate 120 may be formed of a plastic material having flexibility.

A bonding layer BDL is disposed between the first substrate 110 and the second substrate 120. The bonding layer BDL may be formed of a material which may be cured by various curing methods to bond the first substrate 110 and the second substrate 120. The bonding layer BDL may be disposed only in a partial area between the first substrate 110 and the second substrate 120 or may be disposed in the entire area therebetween.

A plurality of second pad electrodes PAD2 are disposed on a rear surface of the second substrate 120. The plurality of second pad electrodes PAD2 are electrodes which transmit a signal from a driving component disposed on the rear surface of the second substrate 120 to a plurality of side lines SRL to be described below and a plurality of first pad electrodes PAD1 and a plurality of wiring lines on the first substrate 110. The plurality of second pad electrodes PAD2 are disposed in an end portion of the second substrate 120 in the non-active area NA to be electrically connected to the side line SRL which covers the end portion of the second substrate 120.

At this time, the plurality of second pad electrodes PAD2 may be also disposed to correspond to the plurality of pad areas. The plurality of first pad electrodes PAD1 may be disposed to correspond to the plurality of second pad electrodes PAD2, respectively, and then the first pad electrode PAD1 and the second pad electrode PAD2 which overlap each other may be electrically connected through the side line SRL.

Each of the plurality of second pad electrodes PAD2 includes a plurality of conductive layers. For example, each of the plurality of second pad electrodes PAD2 includes a fourth conductive layer PE2a, a fifth conductive layer PE2b, and a sixth conductive layer PE2c.

First, the fourth conductive layer PE2a is disposed below the second substrate 120. The fourth conductive layer PE2a may be configured by a conductive material such as copper (Cu), aluminum (Al), molybdenum (Mo), nickel (Ni), titanium (Ti), and chrome (Cr), or an alloy thereof, but is not limited thereto.

The fifth conductive layer PE2b is disposed below the fourth conductive layer PE2a. The fifth conductive layer PE2b may be configured by a conductive material, such as copper (Cu), aluminum (Al), molybdenum (Mo), nickel (Ni), titanium (Ti), and chrome (Cr), or an alloy thereof, but is not limited thereto.

The sixth conductive layer PE2c is disposed below the fifth conductive layer PE2b. The sixth conductive layer PE2c may be formed of a conductive material, for example, a transparent conductive material, such as indium tin oxide (ITO) and indium zinc oxide (IZO), but is not limited thereto.

The second protection layer 121 is disposed in the remaining area of the second substrate 120. The second protection layer 121 may protect various wiring lines and driving components formed on the second substrate 120. The second protection layer 121 may be configured by an organic insulating material, and for example, configured by benzocyclobutene or an acrylic organic insulating material, but is not limited thereto.

A driving component including a plurality of flexible films and a printed circuit board may be disposed on a rear surface of the second substrate 120. The plurality of flexible films are components in which various components such as a data driver IC are disposed on a base film having a ductility to supply signals to the plurality of sub pixels SP. The printed circuit board is a component which is electrically connected to the plurality of flexible films to supply signals to the driving IC. On the printed circuit board, various components for supplying various signals to the driving IC may be disposed.

For example, the fourth conductive layer PE2a and/or the fifth conductive layer PE2b of the second pad electrode PAD2 extend to the plurality of flexible films disposed on the rear surface of the second substrate 120 to be electrically connected to the plurality of flexible films. The plurality of flexible films may supply various signals to the plurality of side lines SRL, the plurality of first pad electrodes PAD1, the plurality of wiring lines, and the plurality of sub pixels SP through the second pad electrode PAD2. Therefore, the signal from the driving component may be transmitted to the signal line SL and the plurality of sub pixels SP on the front surface of the first substrate 110 through the plurality of second pad electrodes PAD2 of the second substrate 120, the side line SRL, and the plurality of first pad electrodes PAD1 of the first substrate 110.

Next, the plurality of side lines SRL are disposed on the side surfaces of the first substrate 110 and the second substrate 120. The plurality of side lines SRL may electrically connect the plurality of first pad electrodes PAD1 formed on the top surface of the first substrate 110 and the plurality of second pad electrodes PAD2 formed on the rear surface of the second substrate 120. The plurality of side lines SRL may be disposed to enclose the side surface of the display device 100. Each of the plurality of side lines SRL may cover the first pad electrode PAD1 at an end portion of the first substrate 110, a side surface of the first substrate 110, a side surface of the second substrate 120, and the second pad electrode PAD2 at an end portion of the second substrate 120. For example, the plurality of side lines SRL may be formed by a pad printing method using a conductive ink, for example, including silver (Ag), copper (Cu), molybdenum (Mo), and chrome (Cr).

A side insulating layer 140 which covers the plurality of side lines SRL is disposed. The side insulating layer 140 may be formed on the top surface of the first substrate 110, the side surface of the first substrate 110, the side surface of the second substrate 120, and the rear surface of the second substrate 120 to cover the side line SRL. The side insulating layer 140 may protect the plurality of side lines SRL.

At this time, when the plurality of side lines SRL are formed of a metal material, there may be a problem in that external light is reflected from the plurality of side lines SRL or light emitted from the light emitting diode 130 is reflected from the plurality of side lines SRL to be visibly recognized by the user. Therefore, the side insulating layer 140 is configured to include a black material to suppress reflection of the external light. For example, the side insulating layer 140 may be formed by a pad printing method using an insulating material including a black material, for example, a black ink.

A seal member 150 which covers the side insulating layer 140 is disposed. The seal member 150 is disposed to enclose the side surface of the display device 100 to protect the display device 100 from external impacts, moisture, and oxygen. For example, the seal member 150 may be formed of polyimide (PI), poly urethane, epoxy, or acryl based insulating material, but is not limited thereto.

Referring to FIGS. 5 to 7, an optical film MF which covers upper portions of the seal member 150, the side insulating layer 140, and the third passivation layer 115c is disposed in the entire upper area of the first substrate 110. The optical film MF may be a functional film which implements a higher quality of images while protecting the display device 100. For example, the optical film MF may include an anti-scattering film, an anti-glare film, an anti-reflecting film, a low-reflecting film, an Oled transmittance controllable film, a polarizer, or the like, but is not limited thereto.

At this time, an adhering part 118 is disposed between the seal member 150, the side insulating layer 140, and the third passivation layer 115c and the optical film MF. The adhering unit 118 is formed on the front surface of the first substrate 110 to bond between the seal member 150, the side insulating layer 140, and the third passivation layer 115c and the optical film MF. The adhering unit 118 may be formed of a photo curable adhesive material which may be cured by light. For example, the adhering unit 118 may be formed of an acrylic material including a photoresist, but is not limited thereto.

In the present disclosure, the adhering unit 118 and the optical film MF are configured as separate components, but the present disclosure is not limited thereto and the optical film MF and the adhering unit 118 may be configured as one component.

An edge of the seal member 150 and an edge of the optical film MF may be disposed on the same line. The optical film MF having a larger size is attached above the first substrate 110 during the manufacturing process of the display device 100 and the seal member 150 which covers the side insulating layer 140 may be formed. Thereafter, laser is irradiated on the seal member 150 and the optical film MF to correspond to an edge of the display device 100 to cut a part of the seal member 150 and the optical film MF. Accordingly, the size of the display device 100 is adjusted by an outer periphery cutting process of the seal member 150 and the optical film MF and the edge of the display device 100 may be formed to be flat.

The process of disposing the plurality of pad electrodes requires a process of forming a contact hole to electrically connect the plurality of conductive layers of the plurality of pad electrodes, respectively. At this time, when the process of forming a contact hole in an interlayer insulating layer in a position in which the plurality of conductive layers of the pad electrode are disposed is performed after a process of forming a light emitting diode in the active area, the process of forming a contact hole may be performed in a state in which the interlayer insulating layer is cured by the process of forming a light emitting diode. Further, the contact hole is formed after the process of forming a light emitting diode in the active area, so that in a position in which the plurality of conductive layers of the pad electrode are disposed, a plurality of interlayer insulating layers are disposed to cause a high step. Accordingly, residual films of the interlayer insulating layer which remain during the process of forming a contact hole are generated in the contact hole of the pad electrode. Further, as described above, as the contact hole is formed after the process of forming a light emitting diode in the active area, when a plurality of interlayer insulating layers are disposed and a high step is generated in a position in which the plurality of conductive layers of the pad electrode are disposed, the pad electrode may be disposed such that a side surface is exposed by the high step. Further, the side surface of the pad electrode is exposed to various liquid chemicals during the subsequent process so that the side surface of the pad electrode is eroded due to permeation of the liquid chemicals.

Therefore, in the display device 100 according to the exemplary aspect of the present disclosure, a plurality of contact holes are disposed in each of the plurality of first pad electrodes PAD1 to improve the reliability of the first pad electrode PAD1.

Specifically, in the display device 100 according to the exemplary aspect of the present disclosure, even though the residual film of the adhesive layer AD remains in some contact holes during a process of disposing a plurality of contact holes in each of the plurality of first pad electrodes PAD1 to electrically connect the first conducive layer PE1a and the second conductive layer PE1b of the first pad electrode PAD1, in the remaining contact holes, the electrical connection of the first conductive layer PE1a and the second conductive layer PE1b of the first pad electrode PAD1 may be maintained. Therefore, in the display device 100 according to the exemplary aspect of the present disclosure, a plurality of contact holes are disposed in each of the plurality of first pad electrodes PAD1 to improve the reliability of the first pad electrode PAD1.

In the display device 100 according to the exemplary aspect of the present disclosure, an end of the first conductive layer PE1a and an end of the second conductive layer PE1b of the first pad electrode PAD1 are disposed to be covered by each of the first passivation layer 115a and the second passivation layer 115b. Therefore, the defect generated in the side surface of the first pad electrode PAD1 may be minimized.

Specifically, in the non-active area NA, the first passivation layer 115a is disposed to cover the end of the first conductive layer PE1a of the first pad electrode PAD1 and the second passivation layer 115b is disposed to cover the end of the second conductive layer PE1b of the first pad electrode PAD1. Therefore, the first passivation layer 115a and the second passivation layer 115b may be configured to protect the side surface of the first pad electrode PAD1 during the subsequent process while covering the side surface of the first pad electrode PAD1. Therefore, the side surface of the first pad electrode PAD1 may be protected from various liquid chemicals during the subsequent process and the permeation of the liquid chemicals is minimized to minimize the erosion of the first pad electrode PAD1. Accordingly, in the display device 100 according to the exemplary aspect of the present disclosure, an end of the first conductive layer PE1a and an end of the second conductive layer PE1b of the first pad electrode PAD1 are disposed to be covered by each of the first passivation layer 115a and the second passivation layer 115b. Therefore, the defect generated in the side surface of the first pad electrode PAD1 may be minimized and the defect of the pad electrode which generates during the process may be minimized.

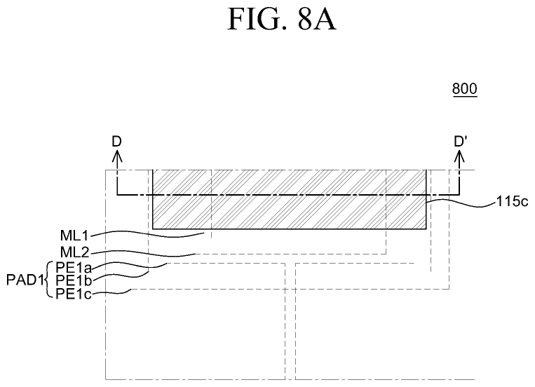

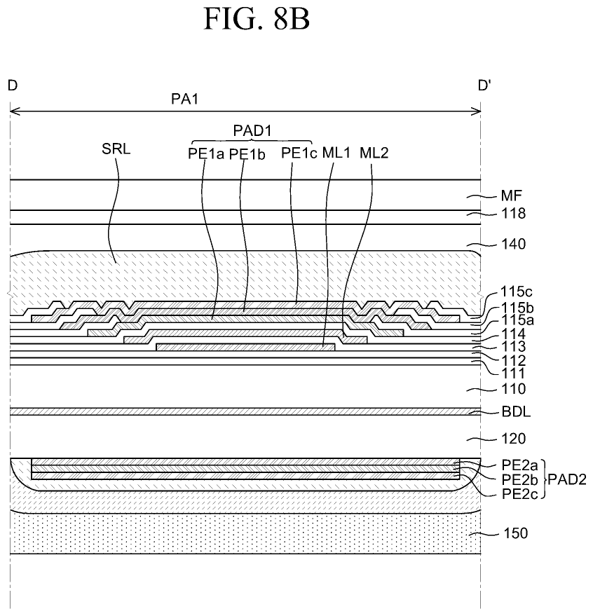

Hereinafter, a display device 800 according to another exemplary aspect of the present disclosure will be described in more detail with reference to FIGS. 8A and 8B.

FIG. 8A is an enlarged plan view of one first pad electrode of a display device according to another exemplary aspect of the present disclosure. FIG. 8B is a cross-sectional view taken along D-D′ of FIG. 8A. The only difference between the display device 100 of FIGS. 1 to 7 and a display device 800 of FIGS. 8A and 8B is that a single contact hole is disposed on one pad electrode, but the other configuration is substantially the same, so that a redundant description will be omitted.

Referring to FIGS. 8A and 8B, a single contact hole is disposed in each of the plurality of first pad electrodes PAD1.

Specifically, the second conductive layer PE1b of one first pad electrode PAD1 is electrically connected to the first conductive layer PE1a through a contact hole formed in the first passivation layer 115a. A single contact hole is disposed in the first passivation layer 115a on the first conductive layer PE1a of each of the plurality of first pad electrodes PAD1. The second conductive layer PE1b and the first conductive layer PE1a are disposed to be in contact with each other by one contact surface thereof in the contact hole of the first passivation layer 115a. That is, the first conductive layer PE1a and the second conductive layer PE1b of the first pad electrode PAD1 may be electrically connected to each other by one contact hole.

At this time, the first planarization layer 116a may be disposed to be spaced apart from the contact surfaces of the first conductive layer PE1a and the second conductive layer PE1b of the first pad electrode PAD1. Further, even though it is not illustrated in the drawings, the adhesive layer AD may be also disposed to be spaced apart from the contact surface of the first conductive layer PE1a and the second conductive layer PE1b of the first pad electrode PAD1. Therefore, an interlayer insulating layer, such as the first planarization layer 116a and the adhesive layer AD is not disposed on a contact surface of the first conductive layer PE1a and the second conductive layer PE1b. Further, the first conductive layer PE1a and the second conductive layer PE1b of the first pad electrode PAD1 may be configured to be electrically connected by a single contact hole.

In the display device 800 according to another exemplary aspect of the present disclosure, a single contact hole is disposed in each of the plurality of first pad electrodes PAD1 to minimize the heat generated from the plurality of the first pad electrode PAD1.

Specifically, the second conductive layer PE1b of one first pad electrode PAD1 is electrically connected to the first conductive layer PE1a through a contact hole formed in the first passivation layer 115a. A single contact hole is formed in the first passivation layer 115a on the first conductive layer PE1a of each of the plurality of first pad electrodes PAD1. The second conductive layer PE1b and the first conductive layer PE1a are disposed to be in contact with each other by one contact surface thereof in the contact hole of the first passivation layer 115a. Accordingly, the first conductive layer PE1a and the second conductive layer PE1b of the first pad electrode PAD1 may be electrically connected to each other by one contact hole. Therefore, a single contact hole is disposed in the first conductive layer PE1a and the second conductive layer PE1b of the first pad electrode PAD1 so that a current density of the first pad electrode PAD1 may be reduced. As a current density of the first pad electrode PAD1 is reduced, the heat generated from the first pad electrode PAD1 may be also minimized. Accordingly, in the display device 800 according to another exemplary aspect of the present disclosure, a single contact hole is disposed in each of the plurality of first pad electrodes PAD1 to minimize the heat generated from the plurality of the first pad electrode PAD1 and improve the reliability of the display device 800.

The exemplary aspects of the present disclosure may also be described as follows:

According to an aspect of the present disclosure, a display device includes a substrate including an active area in which the plurality of sub pixels is disposed and a non-active area which encloses the active area; a plurality of pad electrodes disposed on the substrate in the non-active area to transmit a signal to the plurality of sub pixels and each including a first conductive layer, a second conductive layer on the first conductive layer, and a third conductive layer on the second conductive layer; a first passivation layer extending from the active area to cover an end of the first conductive layer; and a second passivation layer extending from the active area to cover an end of the second conductive layer.

A contact hole may be disposed in the first passivation layer on the first conductive layer of each of the plurality of pad electrodes, and the second conductive layer and the first conductive layer may be in contact with each other by a contact surface thereof in the contact hole.

The display device may further comprise a first planarization layer covering the first passivation layer.

The first planarization layer may be disposed to be spaced apart from the contact surface of the first conductive layer and the second conductive layer.

The first passivation layer and the second passivation layer may be disposed to be in contact with each other in an area between the plurality of pad electrodes to seal an end of the first planarization layer in the area.

The display device may further comprise an adhesive layer extending from the active area to be disposed between the second passivation layer and the third conductive layer.

The adhesive layer may be disposed to be spaced apart from the contact surface of the first conductive layer and the second conductive layer.

The contact hole may be a single contact hole, and the second conductive layer and the first conductive layer may be in contact with each other by one contact surface thereof in the single contact hole.

the contact hole may be a plurality of contact holes, and the second conductive layer and the first conductive layer may be in contact with each other by a plurality of contact surfaces thereof in the plurality of the contact holes.

The display device may further comprise a first planarization layer disposed between the first passivation layer and the second passivation layer.

The first planarization layer may be disposed to be spaced apart from the plurality of pad electrodes.

The first passivation layer and the second passivation layer may be disposed to be in contact with each other in an area between the plurality of pad electrodes to seal an end of the first planarization layer in the area.

The display device may further comprise an adhesive layer extending from the active area to be disposed between the second passivation layer and the third conductive layer; and a third passivation layer disposed on the adhesive layer and covers an end of the third conductive layer.

The first passivation layer may be disposed to enclose the first conductive layer.

The second passivation layer may be disposed to enclose the second conductive layer.

The display device may further comprise a plurality of metal layers disposed between the plurality of pad electrodes and the substrate and insulated from the plurality of pad electrodes.

The plurality of metal layers may include a first metal layer and a second metal layer on the first metal layer.

The display device may further comprise a plurality of transistors disposed in each of the plurality of sub pixels; and a plurality of capacitors disposed in the plurality of sub pixels.

The first metal layer may be formed of the same material as gate electrodes of the plurality of transistors and the second metal layer may be formed of the same material as capacitor electrodes of the plurality of capacitors.

An area of the plurality of metal layers on the plane may be smaller than an area of the plurality of pad electrodes on the plane.

The plurality of metal layers may be electrically floated.

The display device may further comprise a plurality of transistors disposed in each of the plurality of sub pixels.

The first conductive layer may be formed of the same material as source electrodes and drain electrodes of the plurality of transistors.

The first passivation layer may be disposed on the plurality of transistors

The display device may further comprise a plurality of light emitting diode disposed in each of the plurality of sub pixels; and a reflection plate disposed below the light emitting diode.

The second conductive layer may be formed of the same material as the reflection plate.

The display device may further comprise a connection electrode electrically connecting the reflection plate and the plurality of light emitting diodes.

The third conductive layer may be formed of the same material as the connection electrode.

The second passivation layer may be disposed on the reflection plate.

The active area further may include a plurality of gate driving areas extending from the plurality of sub pixels and including a gate driver disposed therein. The plurality of pad electrodes may include a gate pad for transmitting a signal to the gate driver.

Active layers of a plurality of transistors disposed in the plurality of sub pixels and active layers of a plurality of transistors disposed in the gate driver may be formed by oxide semiconductor, amorphous silicon, or polysilicon.

The plurality of transistors disposed in the gate driver may include the active layers formed of different materials.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including a display area including a plurality of sub pixels is disposed and a non-active area adjacent to the active area;
a plurality of pad electrodes disposed on the substrate in the non-active area to transmit a signal to the plurality of sub pixels and each including a first conductive layer, a second conductive layer disposed on the first conductive layer, and a third conductive layer disposed on the second conductive layer;
a first passivation layer extending from the active area and disposed on a portion of the first conductive layer; and
a second passivation layer extending from the active area and covering an end of the second conductive layer.

2. The display device according to claim 1, wherein the first passivation layer disposed on the first conductive layer of each of the plurality of pad electrodes has a contact hole, and the second conductive layer and the first conductive layer are in contact with each other by a contact surface thereof in the contact hole.

3. The display device according to claim 2, further comprising a first planarization layer covering the first passivation layer,
wherein the first planarization layer is spaced apart from the contact surface of the first conductive layer and the second conductive layer.

4. The display device according to claim 3, wherein the first passivation layer and the second passivation layer are in contact with each other in an area between the plurality of pad electrodes.

5. The display device according to claim 2, further comprising an adhesive layer extending from the active area and disposed between the second passivation layer and the third conductive layer,
wherein the adhesive layer is spaced apart from the contact surface of the first conductive layer and the second conductive layer.

6. The display device according to claim 2, wherein the contact hole is a single contact hole, and the second conductive layer and the first conductive layer are in contact with each other by one contact surface thereof in the single contact hole; or
the contact hole are a plurality of contact holes, and the second conductive layer and the first conductive layer are in contact with each other by a plurality of contact surfaces thereof in the plurality of the contact holes.

7. The display device according to claim 1, further comprising a first planarization layer disposed between the first passivation layer and the second passivation layer,
wherein the first planarization layer is spaced apart from the plurality of pad electrodes.

8. The display device according to claim 7, wherein the first passivation layer and the second passivation layer are disposed to be in contact with each other in an area between the plurality of pad electrodes.

9. The display device of claim 1, further comprising:
an adhesive layer extending from the active area and disposed between the second passivation layer and the third conductive layer; and
a third passivation layer disposed on the adhesive layer and on portion of the third conductive layer.

10. The display device according to claim 1, wherein the first passivation layer encloses the first conductive layer.

11. The display device according to claim 1, wherein the second passivation layer surrounds the second conductive layer.

12. The display device according to claim 1, further comprising a plurality of metal layers disposed between the plurality of pad electrodes and the substrate,
wherein the plurality of metal layers include a first metal layer and a second metal layer disposed on the first metal layer.

13. The display device according to claim 12, further comprising:
a plurality of transistors disposed at each of the plurality of sub pixels; and
a plurality of capacitors disposed in the plurality of sub pixels,
wherein the first metal layer is formed of a same material as gate electrodes of the plurality of transistors and the second metal layer is formed of a same material as capacitor electrodes of the plurality of capacitors.

14. The display device according to claim 13, wherein an area of the plurality of metal layers on a plane is smaller than an area of the plurality of pad electrodes on the plane.

15. The display device according to claim 13, wherein the plurality of metal layers is electrically floated.

16. The display device according to claim 1, further comprising a plurality of transistors disposed in each of the plurality of sub pixels,
wherein the first conductive layer is formed of a same material as source electrodes and drain electrodes of the plurality of transistors.

17. The display device according to claim 16, wherein the first passivation layer is disposed on the plurality of transistors.

18. The display device according to claim 1, further comprising:
a plurality of light emitting diode disposed in each of the plurality of sub pixels; and
a reflection plate disposed below the light emitting diode,
wherein the second conductive layer is formed of a same material as the reflection plate.

19. The display device according to claim 18, further comprising a connection electrode electrically connecting the reflection plate and the plurality of light emitting diodes,
wherein the third conductive layer is formed of a same material as the connection electrode.

20. The display device according to claim 18, wherein the second passivation layer is disposed on the reflection plate.

21. The display device according to claim 1, wherein the active area further includes a plurality of gate driving areas extending from the plurality of sub pixels and including a gate driver.

22. The display device according to claim 21, wherein active layers of a plurality of transistors disposed at the plurality of sub pixels and active layers of a plurality of transistors disposed at the gate driver include at least one of oxide semiconductor, amorphous silicon, low temperature polysilicon, and polysilicon.

23. The display device according to claim 22, wherein the plurality of transistors disposed in the gate driver includes the active layers different from the active layers of the subpixel.

24. The display device according to claim 22, wherein the plurality of metal layers is insulated from the plurality of pad electrodes.

25. A display device, comprising:
a substrate defined by a display area including a plurality of sub pixels and a non-active area adjacent to the active area;
a first pad electrode comprising first, second and third conductive layers and disposed in the non-active area to transmit a signal to the plurality of sub pixels and; and
a first passivation layer extending from the active area, disposed on the first conductive layer and having at least one contact hole,
wherein the first conductive layer and the second conductive layer are in contact through the at least one contact hole.

26. The display device according to claim 25, further comprising a second passivation layer extending from the active area and covering one end of the second conductive layer.

27. The display device according to claim 26, further comprising a first planarization layer disposed on the first conductive layer and the first passivation layer.

28. The display device according to claim 27, wherein the first planarization layer covers a portion of the first passivation layer where the first passivation layer overlaps the first pad electrode.

29. The display device according to claim 27, wherein the second passivation layer is disposed on the second conductive layer and the first planarization layer.
